(19) United States
(12) Patent Application Publication
(10) Pub. No.: US 2015/0144992 A1
(43) Pub. Date: May 28, 2015

(54) POWER SEMICONDUCTOR DEVICE

(71) Applicant: SAMSUNG ELECTRO-MECHANICS CO., LTD., Suwon-Si (KR)

(72) Inventors: Chang Su JANG, Suwon-Si (KR); In Hyuk Song, Suwon-Si (KR); Jae Hoon Park, Suwon-Si (KR); Dong Soo Seo, Suwon-Si (KR)

(73) Assignee: SAMSUNG ELECTRO-MECHANICS CO., LTD., Suwon-si (KR)

(21) Appl. No.: 14/280,464

(22) Filed: May 16, 2014

(30) Foreign Application Priority Data
Nov. 28, 2013 (KR) 10-2013-0146405

(51) Int. Cl. H01L 29/06; H01L 29/73

(52) U.S. Cl. CPC H01L 29/0661; H01L 29/73
USPC 257/139

(57) ABSTRACT

A power semiconductor device may include: an active region having a current flowing through a channel formed therein at the time of a turn-on operation of the power semiconductor device; an termination region formed in the vicinity of the active region; a plurality of trenches formed in a length direction of the active region; a first conductivity type hole accumulating region formed below the channel in the active region; and a first conductivity type electric field limiting region formed in the termination region. The electric field limiting region is formed so as to at least partially cover a trench positioned at a boundary between the active region and the termination region.

### CROSS-REFERENCE TO RELATED APPLICATION

This application claims the benefit of Korean Patent Application No. 10-2013-0146405 filed on Nov. 28, 2013, with the Korean Intellectual Property Office, the disclosure of which is incorporated herein by reference.

### BACKGROUND

The present disclosure relates to a power semiconductor device and a method of manufacturing the same.

An insulated gate bipolar transistor (IGBT) is a transistor manufactured to have bipolarity by forming a gate using a metal oxide semiconductor (MOS) and forming a p-type collector layer on a rear surface thereof.

Since the development of power metal oxide semiconductor field effect transistors (MOSFETs) in the related art, such transistors have been used in fields requiring high speed switching characteristics.

However, due to structural limitations of MOSFETs, bipolar transistors, thyristors, gate turn-off thyristors (GTOs), and the like, have been used in fields requiring high voltages.

Since IGBTs have characteristics such as a low forward loss and rapid switching speeds, the application of IGBTs to fields that may not be appropriate for the use of existing thyristors, bipolar transistors, MOSFETs, and the like, has increased.

The operational principle of IGBTs will be described hereinafter. In the case in which an IGBT device is turned on, a voltage applied to an anode has a higher level than a voltage applied to a cathode, and when a voltage having a level higher than that of a threshold voltage of the IGBT device is applied to a gate electrode, a polarity of a surface of a p-type body region positioned at a lower end of the gate electrode is inverted, such that an n-type channel is formed.

An electron current injected into a drift region through an n-type channel formed in such a manner induces the injection of a hole current from a high-concentration p-type collector layer positioned in a lower portion of the IGBT device, in a manner similar to that of abase current of a bipolar transistor.

Due to the injection of these minority carriers in a high concentration, a conductivity modulation phenomenon in which conductivity in the drift region is increased by several tens to several hundreds of times occurs.

Unlike MOSFETs, in the case of IGBTs, a resistance component in the drift region may be greatly reduced in size due to the conductivity modulation phenomenon. Therefore, IGBTs may have very high levels of voltage applied thereto.

A current flowing in the cathode is divided into an electron current flowing through the channel and a hole current flowing through a junction between a p-type body and an n-type drift region.

Since IGBTs have a PNP structure between anodes and cathodes, a diode is not embedded in IGBTs unlike in the case of MOSFETs, such that a separate diode should be connected in reverse in parallel with IGBTs.

IGBTs have characteristics such as allowing for the maintenance of blocking voltages, decreased conduction loss, and increased switching speeds.

According to the related art, magnitudes of voltages applied to IGBTs have increased. Therefore, improvements in the durability of IGBT devices have been demanded.

Particularly, in order to significantly increase the conductivity modulation, a hole accumulating region may be formed below the channel.

Such hole accumulating regions, inserted in order to improve conduction loss of IGBTs, significantly contribute to improvements in current density, but may lead to decreases in positive effects of p-type impurities in a p-type well region positioned at a boundary between an active region and an end portion of power semiconductor devices.

Therefore, a breakdown voltage (BV) may be decreased at the boundary between the active region and the end portion of power semiconductor devices.

Patent Document 1, related to a semiconductor device having a junction structure, discloses that a peripheral region has a blocking voltage higher than that of a cell region.

### RELATED ART DOCUMENT

(Patent Document 1) Korean Patent Laid-Open Publication No. 2006-0066655

### SUMMARY

An aspect of the present disclosure may provide a power semiconductor device capable of improving a breakdown voltage at a boundary between an active region and an termination region thereof.

According to an aspect of the present disclosure, a power semiconductor device may include: an active region having a current flowing through a channel formed therein at the time of a turn-on operation of the power semiconductor device; an termination region formed in the vicinity of the active region; a plurality of trenches formed in a length direction of the active region; a first conductivity type hole accumulating region formed below the channel in the active region; and a first conductivity type electric field limiting region formed at an upper portion of the termination region, wherein the electric field limiting region is formed so as to at least partially cover a trench positioned at a boundary between the active region and the termination region.

The electric field limiting region may at least partially cover a lower portion of the trench positioned at the boundary between the active region and the termination region.

The electric field limiting region may be formed at a depth deeper than that of the trench positioned at the boundary between the active region and the termination region.

A depth of the trench positioned at the boundary between the active region and the termination region may be shallower than that of a trench adjacent thereto.

A width of the trench positioned at the boundary between the active region and the termination region may be narrower than that of a trench adjacent thereto.

According to another aspect of the present disclosure, a power semiconductor device may include: a first conductivity type first semiconductor region; a first conductivity type second semiconductor region formed on the first semiconductor region and having a concentration of impurities higher than that of the first semiconductor region; a second conductivity type third semiconductor region formed on the second semiconductor region; a first conductivity type fourth semiconductor region formed in an inner portion of an upper portion of the third semiconductor region; a plurality of trenches formed in a lengthwise direction thereof so as to penetrate from the fourth semiconductor region into the first semiconductor region; and a second conductivity type electric field limiting region formed on the first semiconductor region so as to at least partially cover a trench among the plurality of trenches positioned in the outermost position.

The electric field limiting region may at least partially cover a lower portion of the trench among the plurality of trenches positioned in the outermost position.

The electric field limiting region may cover a portion of the second semiconductor region positioned at an outer side of the trench among the plurality of trenches positioned in the outermost position.

The electric field limiting region may be formed at a depth deeper than that of the trench among the plurality of trenches positioned in the outermost position.

A depth of the trench among the plurality of trenches positioned in the outermost position may be shallower than that of a trench adjacent thereto.

A width of the trench among the plurality of trenches positioned in the outermost position may be narrower than that of a trench adjacent thereto.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a schematic perspective view of a power semiconductor device according to an exemplary embodiment of the present disclosure;

FIG. 2 is a schematic cross-sectional view of the power semiconductor device according to an exemplary embodiment of the present disclosure;

FIG. 3 is a schematic cross-sectional view of a power semiconductor device according to another exemplary embodiment of the present disclosure;

FIG. 4 is a schematic cross-sectional view of a power semiconductor device according to another exemplary embodiment of the present disclosure; and

FIG. 5 is a schematic cross-sectional view of a power semiconductor device according to another exemplary embodiment of the present disclosure.

### DETAILED DESCRIPTION

Hereinafter, embodiments of the present disclosure will be described in detail with reference to the accompanying drawings. The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art. In the drawings, the shapes and dimensions of elements may be exaggerated for clarity, and the same reference numerals will be used throughout to designate the same or like elements.

A power switch may be implemented by any one of a power metal oxide semiconductor field effect transistor (MOSFET), an insulated gate bipolar transistor (IGBT), several types of thyristors, and devices similar to the above-mentioned devices. Most of new technologies disclosed herein will be described based on the IGBT. However, several exemplary embodiments of the present disclosure disclosed herein are not limited to the IGBT, but may also applied to other types of power switch technologies including a power MOSFET and several types of thyristors in addition to the IGBT. Further, several exemplary embodiments of the present disclosure will be described as including specific p-type and n-type regions. However, conductivity types of several regions disclosed herein may be similarly applied to devices having conductivity types opposite thereto.

In addition, an n-type or a p-type used herein may be defined as a first conductivity type or a second conductivity type. Meanwhile, the first and second conductivity types mean different conductivity types.

Further, generally, ‘+’ means a state in which a region is heavily doped and ‘−’ means a state that a region is lightly doped.

Hereinafter, although the case in which the first conductivity type is the n-type and the second conductivity type is the p-type will be described in order to make a description clear, the present disclosure is not limited thereto.

In addition, although the case in which a first semiconductor region is a drift region, a second semiconductor region is a hole accumulating region, a third semiconductor region is a body region, and a fourth semiconductor region is an emitter region will be described, the present disclosure is not limited thereto.

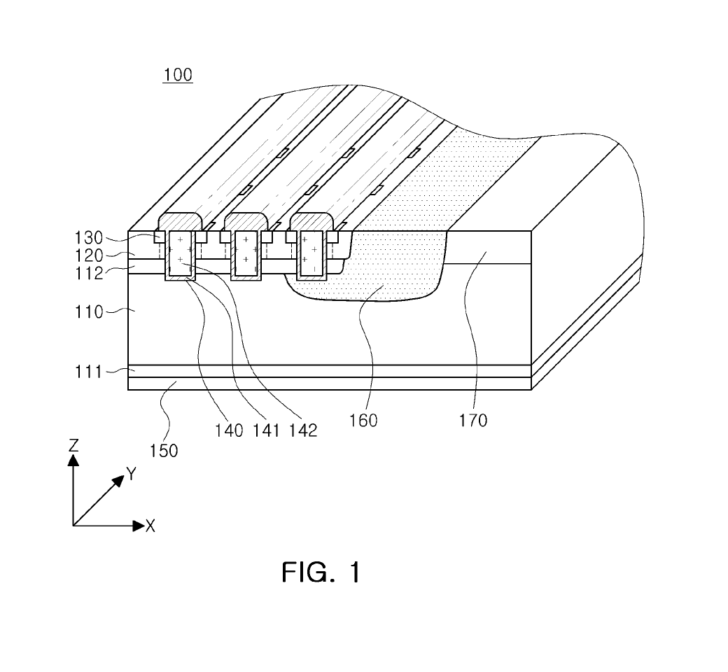

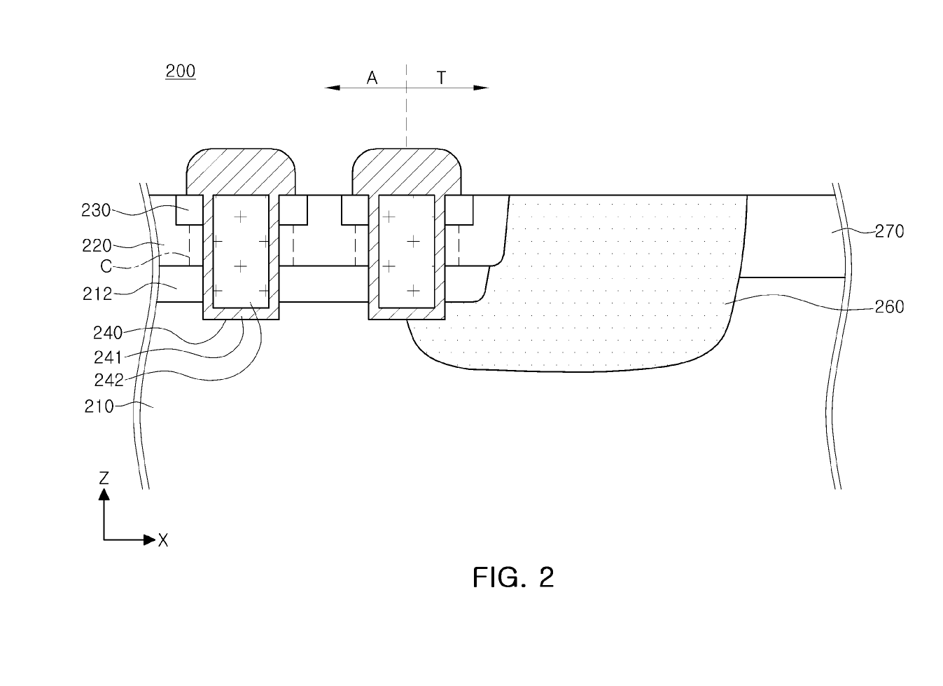

FIG. 1 is a schematic perspective view of a power semiconductor device 100 according to an exemplary embodiment of the present disclosure, and FIG. 2 is a schematic cross-sectional view of the power semiconductor device 100 according to an exemplary embodiment of the present disclosure.

A structure of the power semiconductor device 100 according to an exemplary embodiment of the present disclosure will be described with reference to FIGS. 1 and 2.

The power semiconductor device 100 according to an exemplary embodiment of the present disclosure may mainly include an active region A having a current flowing therein at the time of a turn-on operation of the power semiconductor device 100 and an termination region T formed in the vicinity of the active region A and supporting a breakdown voltage.

First, a structure of the active region A will be described.

The active region A may include a drift region 110, a hole accumulating region 112, a body region 120, an emitter region 130, and a collector region 150.

The drift region 110 may be formed by implanting n-type impurities at a low concentration.

Therefore, the drift region 110 may have a relatively thick thickness in order to maintain a breakdown voltage of the power semiconductor device.

The drift region 110 may further include a buffer region 111 formed therebelow.

The buffer region 111 may be formed by implanting n-type impurities into a rear surface of the drift region 110.

The buffer region 111 may serve to block extension of a depletion region of the power semiconductor device at the time of the extension of the depletion region, thereby assisting in maintaining a breakdown voltage of the power semiconductor device.

Therefore, in the case in which the buffer region 111 is formed, a thickness of the drift region 110 may be decreased, such that the power semiconductor device may be miniaturized.

The drift region 110 may have the body region 120 formed thereon by implanting p-type impurities.

The body region 120 may have a conductivity type corresponding to a p-type to form a pn junction with the drift region 110.

The body region 120 may have the emitter region 130 formed in an inner portion of an upper surface thereof by implanting n-type impurities at a high concentration.

Trenches 140 may be formed from the emitter region 130 to the drift region 110 through the body region 120.

That is, the trenches 140 may penetrate from the emitter region 130 into a portion of the drift region 110.

The trenches 140 may be formed in a lengthwise direction thereof (y direction) and may be arranged at predetermined intervals in a direction (x direction) perpendicular to the lengthwise direction.

The trench 140 may have a gate insulating layer 141 formed at a portion at which it contacts the drift region 110, the body region 120, and the emitter region 130.

The gate insulating layer 141 may be formed of a silicon oxide (SiO₂), but is not limited thereto.

The trench 140 may have a conductive material 142 filled therein.

The conductive material 142 may be a poly-silicon (poly-Si) or a metal, but is not limited thereto.

The conductive material 142 may be electrically connected to a gate electrode (not shown) to control an operation of the power semiconductor device 100 according to an exemplary embodiment of the present disclosure.

In the case in which a positive voltage is applied to the conductive material 142, a channel C may be formed in the body region 120.

In detail, in the case in which the positive voltage is applied to the conductive material 142, electrons present in the body region 120 may be pulled toward the trench 140 and be collected in the trench 140, such that the channel C may be formed.

That is, electrons and holes may be recombined with each other due to a pn junction, such that the trench 140 in a depletion region in which carriers are not present attracts the electrons to form the channel C, whereby a current may flow.

The drift region 110 or the buffer region 111 may have the collector region 150 formed therebelow by implanting p-type impurities.

In the case in which the power semiconductor device is the IGBT, the collector region 150 may provide holes to the power semiconductor device.

Due to injection of the holes, which are minority carriers, at a high concentration, a conductivity modulation that conductivity in the drift region is increased several ten or several hundred times occurs.

Particularly, in the case in which the hole accumulating layer 112 of which a concentration of n-type impurities is higher than that of the drift region 110 is formed between the drift region 110 and the body region 120, the hole accumulating layer 112 may significantly increase an amount of accumulated holes to significantly increase the conductivity modulation, thereby decreasing loss at the time of the turn-on operation of the power semiconductor device.

In the case in which the power semiconductor device is the MOSFET, the collector region 150 may have a conductivity type corresponding to an n-type.

The emitter region 130 and the body region 120 may have an emitter metal layer (not shown) formed on exposed upper surfaces thereof, and the collector region 150 may have a collector metal layer (not shown) formed on a lower surface thereof.

Next, a structure of the termination region T will be described.

The termination region T may have a second conductivity type electric field limiting region 160 and a second conductivity type guard ring 170 formed therein.

A concentration of impurities of the electric field limiting region 160 may be higher than that of the guard ring 170.

The electric field limiting region 160 may cover the trench 140 positioned at a boundary between the active region A and the termination region T.

That is, the electric field limiting region 160 may cover the trench 140 positioned at the outermost of the active region A.

Here, the meaning that the electric field limiting region 160 covers the trench 140 is that the electric field limiting region 160 is injected or diffused from the termination region T to a portion of the active region A to prevent the hole accumulating region 112 injected or diffused to a portion of the termination region T and the drift region 110 from directly contacting each other.

The electric field limiting region 160 may be formed at a depth deeper than that of the trench 140 in order to cover the trench 140 positioned at the boundary between the active region A and the termination region T.

In the case in which the hole accumulating region 112 is formed up to a portion of the termination region T, it may be difficult to support an electric field only with the guard ring 170 due to the high concentration of the impurities of the hole accumulating region 112.

That is, in the case in which the electric field limiting region 160 is not present, performance of the guard ring 170 supporting the electric field may be decreased due to the high concentration of the impurities of the hole accumulating region 112.

Therefore, the electric field may be concentrated on a lower corner portion of the trench 140 positioned at the boundary between the active region A and the termination region T, and the breakdown voltage may be rapidly decreased.

However, in the power semiconductor device according to an exemplary embodiment of the present disclosure, since the electric field limiting region 160 encloses the lower corner portion of the trench 140 positioned at the boundary between the active region A and the termination region T, concentration of the electric field may be prevented.

The concentration of the electric field may be prevented, thereby increasing the breakdown voltage of the power semiconductor device.

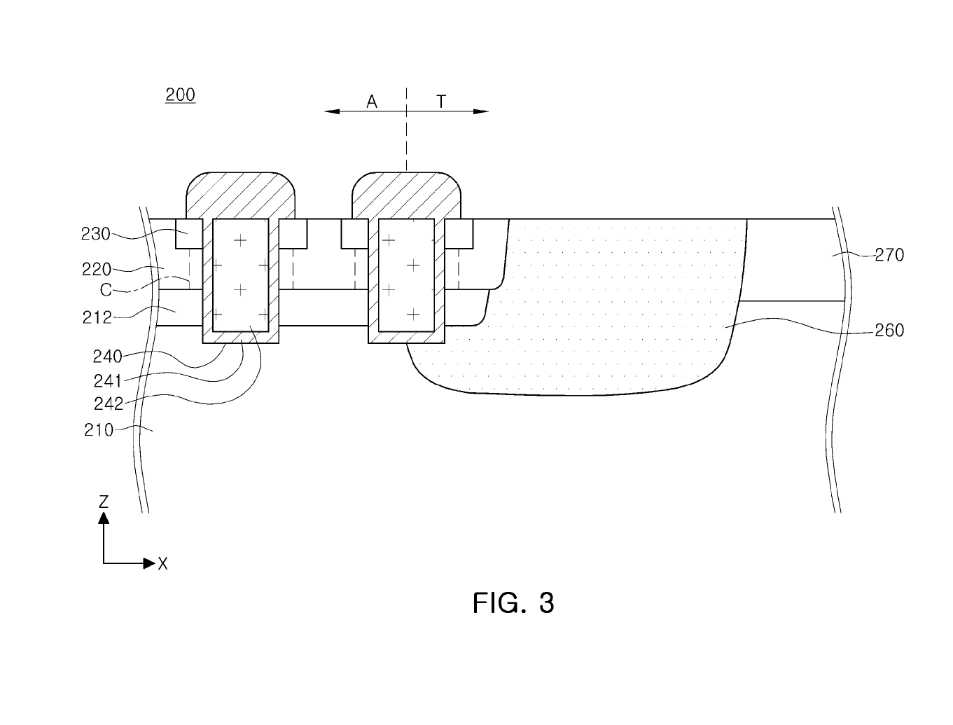

FIG. 3 is a schematic cross-sectional view of a power semiconductor device 200 according to another exemplary embodiment of the present disclosure.

Hereinafter, a structure of the power semiconductor device 200 that is different from that of the power semiconductor device 100 according to an exemplary embodiment of the present disclosure described above will be described with reference to FIG. 3, and a description for a structure of the power semiconductor device 200 that is the same as that of the power semiconductor device 100 according to an exemplary embodiment of the present disclosure described above will be omitted.

An electric field limiting region 260 of the power semiconductor device 200 according to another exemplary embodiment of the present disclosure may cover a portion of a lower portion of a trench 240 positioned at a boundary between an active region A and an termination region T.

Since the electric field limiting region 260 is formed using second conductivity type impurities, a current may not flow to a portion contacting a hole accumulating region 212.

Therefore, the electric field limiting region 260 may cover the portion of the lower portion of the trench 240 positioned at the boundary between the active region A and the termination region T, thereby allowing the current to flow toward the active region A of the trench 240.

In addition, in the power semiconductor device 200 according to another exemplary embodiment of the present disclosure, since the electric field limiting region 260 encloses a lower corner portion positioned at the termination region T side in the trench 240 positioned at the boundary between the active region A and the termination region T, concentration of the electric field may be prevented.

The concentration of the electric field may be prevented, thereby increasing the breakdown voltage of the power semiconductor device 200.

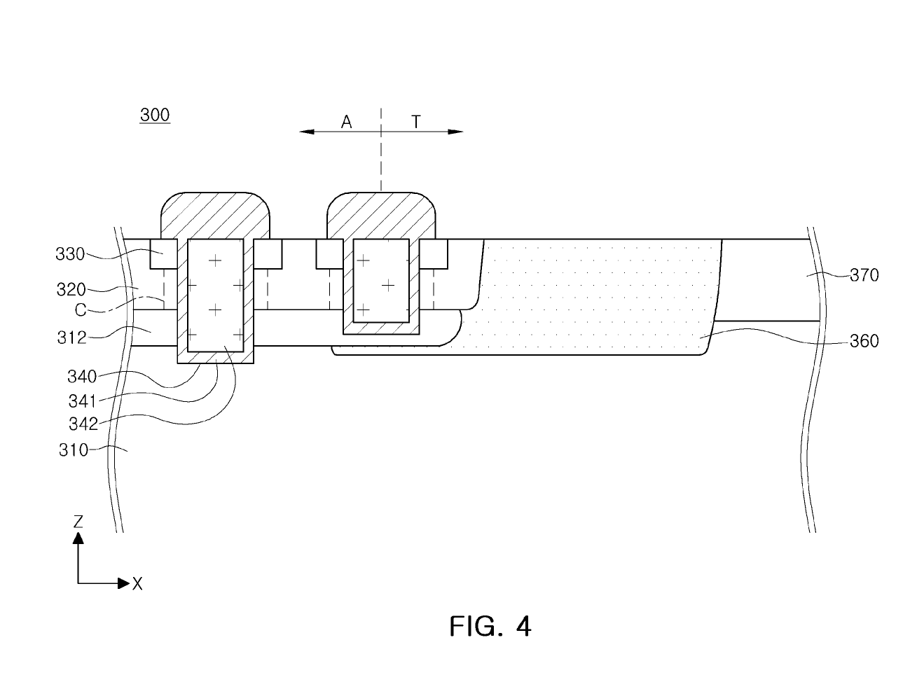

FIG. 4 is a schematic cross-sectional view of a power semiconductor device 300 according to another exemplary embodiment of the present disclosure.

Hereinafter, a structure of the power semiconductor device 300 that is different from that of the power semiconductor device 100 according to an exemplary embodiment of the present disclosure described above will be described with reference to FIG. 4, and a description for a structure of the power semiconductor device 300 that is the same as that of the power semiconductor device 100 according to an exemplary embodiment of the present disclosure described above will be omitted.

In the power semiconductor device 300 according to another exemplary embodiment of the present disclosure, a trench 340 formed at a boundary between an active region A and an termination region T may have a depth shallower than that of a trench 340 adjacent thereto.

The electric field limiting region 360 needs to be formed at the depth deeper than that of the trench 340 so as to at least partially cover the trench 340 in order to increase the breakdown voltage of the power semiconductor device 300. Therefore, the depth of the electric field limiting region 360 may be decreased by decreasing the depth of the trench 340 formed at the boundary between the active region A and the termination region T.

The breakdown voltage (BV) is decreased at a portion having a large curvature since the electric field is concentrated thereon. Therefore, the depth of the trench 340 formed at the boundary between the active region A and the termination region T is decreased to significantly decrease the portion on which the electric field is concentrated, whereby the breakdown voltage may be improved.

In addition, the depth of the electric field limiting region 340 is decreased, whereby a process of forming the electric field limiting region 340 may be shortened.

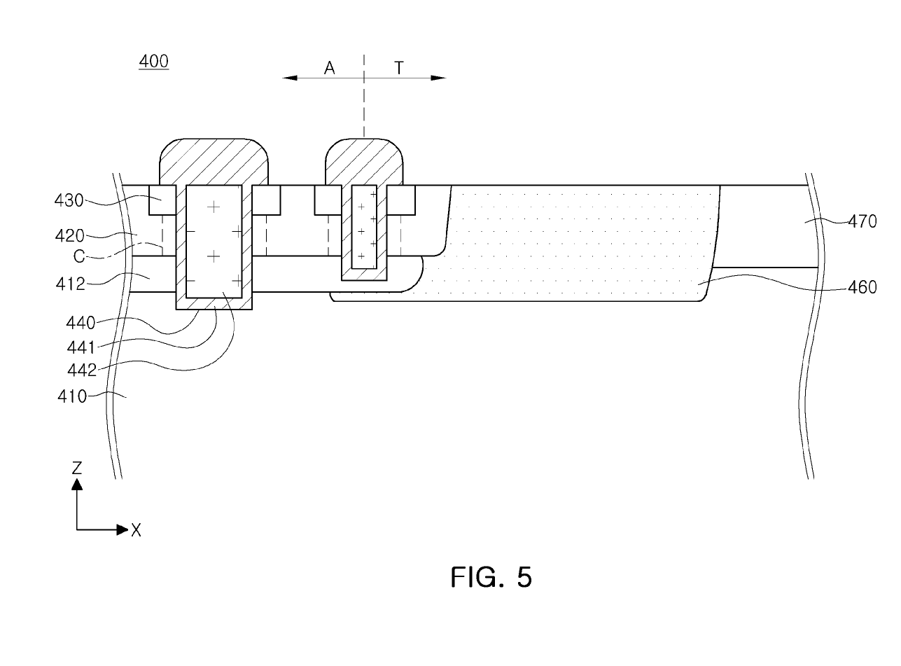

FIG. 5 is a schematic cross-sectional view of a power semiconductor device according to another exemplary embodiment of the present disclosure.

Hereinafter, a structure of the power semiconductor device 400 that is different from that of the power semiconductor device 100 according to an exemplary embodiment of the present disclosure described above will be described with reference to FIG. 5, and a description for a structure of the power semiconductor device 400 that is the same as that of the power semiconductor device 100 according to an exemplary embodiment of the present disclosure described above will be omitted.

In the power semiconductor device 400 according to another exemplary embodiment of the present disclosure, a trench 440 formed at a boundary between an active region A and an termination region T may have a width narrower than that of a trench 440 adjacent thereto.

As described above, a current may not flow to a portion at which the electric field limiting region 460 is formed.

Therefore, the width of the trench 440 formed at the boundary between the active region A and the termination region T is decreased, whereby the active region A may be significantly increased.

As set forth above, in the power semiconductor device according to exemplary embodiments of the present disclosure, since the electric field limiting region is formed so as to at least partially cover the trench positioned at the boundary between the active region and the termination region, the breakdown voltage at the boundary between the active region and the termination region may be improved.

While exemplary embodiments have been shown and described above, it will be apparent to those skilled in the art that modifications and variations could be made without departing from the spirit and scope of the present disclosure as defined by the appended claims.

What is claimed is:

1. A power semiconductor device comprising:
an active region having a current flowing through a channel formed therein at the time of a turn-on operation of the power semiconductor device;
an termination region disposed in the vicinity of the active region;
a plurality of trenches extending in a length direction of the active region;
a first conductivity type hole accumulating region disposed below the channel in the active region; and
a first conductivity type electric field limiting region disposed at an upper portion of the termination region,
wherein the electric field limiting region is configured to at least partially cover a trench positioned at a boundary between the active region and the termination region.

2. The power semiconductor device of claim 1, wherein the electric field limiting region at least partially covers a lower portion of the trench positioned at the boundary between the active region and the termination region.

3. The power semiconductor device of claim 1, wherein the electric field limiting region is formed at a depth deeper than that of the trench positioned at the boundary between the active region and the termination region.

4. The power semiconductor device of claim 1, wherein a depth of the trench positioned at the boundary between the active region and the termination region is shallower than that of a trench adjacent thereto.

5. The power semiconductor device of claim 1, wherein a width of the trench positioned at the boundary between the active region and the termination region is narrower than that of a trench adjacent thereto.

6. A power semiconductor device comprising:
a first conductivity type first semiconductor region;
a first conductivity type second semiconductor region formed on the first semiconductor region and having a concentration of impurities higher than that of the first semiconductor region;
a second conductivity type third semiconductor region formed on the second semiconductor region;
a first conductivity type fourth semiconductor region formed in an inner portion of an upper portion of the third semiconductor region;
a plurality of trenches formed in a lengthwise direction thereof so as to penetrate from the fourth semiconductor region into the first semiconductor region; and
a second conductivity type electric field limiting region formed on the first semiconductor region so as to at least partially cover a trench among the plurality of trenches positioned in the outermost position.

7. The power semiconductor device of claim 6, wherein the electric field limiting region at least partially covers a lower portion of the trench among the plurality of trenches positioned in the outermost position.

8. The power semiconductor device of claim 6, wherein the electric field limiting region covers a portion of the second semiconductor region positioned at an outer side of the trench among the plurality of trenches positioned in the outermost position.

9. The power semiconductor device of claim 6, wherein the electric field limiting region is formed at a depth deeper than that of the trench among the plurality of trenches positioned in the outermost position.

10. The power semiconductor device of claim 6, wherein a depth of the trench among the plurality of trenches positioned in the outermost position is shallower than that of a trench adjacent thereto.

11. The power semiconductor device of claim 6, wherein a width of the trench among the plurality of trenches positioned in the outermost position is narrower than that of a trench adjacent thereto.
